(19) United States
(12) Patent Application Publication
(10) Pub. No.: US 2026/0005094 A1
(43) Pub. Date: Jan. 1, 2026

(54) DEVICE, METHOD AND SYSTEM TO CONDUCT HEAT THROUGH AN ACTIVE LAYER OF AN INTEGRATED CIRCUIT DIE

(71) Applicant: Intel Corporation, Santa Clara, CA (US)

(72) Inventors: Abhishek Anil Sharma, Portland, OR (US); Sagar Suthram, Portland, OR (US); Wilfred Gomes, Portland, OR (US); Anand Murthy, Portland, OR (US); Tahir Ghani, Portland, OR (US); Pushkar Ranade, San Jose, CA (US)

(73) Assignee: Intel Corporation, Santa Clara, CA (US)

(21) Appl. No.: 18/759,173

(22) Filed: Jun. 28, 2024

(51) Int. Cl. H01L 23/367; H01L 23/373; H01L 23/528

(52) U.S. Cl. CPC H01L 23/3675; H01L 23/3736; H01L 23/528; H01L 23/5283

(57) ABSTRACT

Techniques and mechanisms to facilitate a conduction of heat across one or more active layers of an integrated circuit (IC) die. In an embodiment, an IC die comprises vertically stacked active layers, where metallization layers are variously disposed on opposite sides of a first such active layer. A thermal channel structure of the IC die extends through said first active layer, and through the metallization layers, to each of two thermally conductive material layers. Thermal interface structures are variously disposed each between a different respective distal end of the thermal channel structure and a different respective one of the thermally conductive material layers. In another embodiment, the thermal channel structure comprises a substantially columnar main body portion, which is electrically coupled to one or more interconnect structures of the metallization layers.

### BACKGROUND

### 1. Technical Field

This disclosure generally relates to thermal regulation of integrated circuitry and more particularly, but not exclusively, to a thermal conductor which extends through an active layer of an integrated circuit die.

### 2. Background Art

As microprocessors and other integrated circuit (IC) devices continue to advance in complexity and operating rate, the heat generated in such devices during operation tends to increases, and the demands on cooling systems for such devices also escalate. In some cases, circuit components at a localized zone on an IC die—known as a “hotspot”—is prone to raising the temperature at that spot above the average temperature on the IC die. Thus, it may not be sufficient to keep the average temperature of the IC die below a target level, as excessive heating at hotspots may result in localized device malfunctions (even if the overall cooling target is met).

Moreover, it may be important that a microprocessor and cooling system be able to withstand cold temperatures (e.g., minus forty degrees Celsius). For example, a Personal Computer (PC) might be exposed to low temperatures while being shipped from a manufacturer, or a laptop computer might be exposed to freezing temperatures when stored in a person's car overnight. As successive generations of IC designs continue to scale, there is expected to be an increasing premium placed on improvements to thermal regulation for such IC designs.

### BRIEF DESCRIPTION OF THE DRAWINGS

The various embodiments of the present invention are illustrated by way of example, and not by way of limitation, in the figures of the accompanying drawings and in which:

FIG. 1 shows a block diagram illustrating features of an integrated circuit die structure comprising a thermal channel structure according to an embodiment.

FIG. 2 shows a flow diagram illustrating features of a method to provide thermal channel structures of an IC die according to an embodiment.

FIG. 3 shows a cross-sectional side view of an integrated circuit system comprising a thermal conduction structure which extends through an active layer according to an embodiment.

FIG. 4 shows a cross-sectional side view of an integrated circuit system comprising a thermal conduction structure which also facilitates electrical coupling of circuitry according to an embodiment.

FIG. 5 shows a cross-sectional side view of a low-temperature, integrated circuit system which facilitates conduction of heat with die- and package-level active cooling structures according to an embodiment.

FIG. 6 illustrates a view of an example two-phase immersion cooling system for low-temperature operation of an IC die according to an embodiment;

FIG. 7 illustrates a diagram of an example data server machine employing an IC die with a thermal channel structure according to an embodiment; and

FIG. 8 is a block diagram of an example computing device according to an embodiment.

### DETAILED DESCRIPTION

Embodiments discussed herein variously provide techniques and mechanisms for heat to be efficiently conducted across one or more active layers of an integrated circuit (IC) die. In various embodiments, an IC die structure comprises a vertically stacked arrangement of a plurality of layers which each comprise respective non-linear (or “active”) circuit components, such as transistors, diodes and/or the like. A given one such layer (referred to herein as an “active layer”) is coupled to another such active layer via multiple metallization layers, interconnect structures of which facilitate electrical coupling of circuits in a single active layer, circuits in different respective active layers, and/or circuits which are external to said active layers. In one such embodiment, a structure (referred to herein as a “thermal channel structure”) extends through one or more active layers of the IC die structure. The thermal channel structure facilitates a conduction of heat with two or more layers of respective materials (or “material layers” herein)—e.g., wherein one or more such material layers are each to function as a heat sink.

In some embodiments, another structure (referred to herein as a “thermal interface structure”) is disposed between a thermal channel structure and a material layer which extends around at least a portion of said thermal channel structure. By way of illustration and not limitation, in one such embodiment, a thermal channel structure comprises any of various suitable metals (e.g., including copper) which conduct heat via electrons or carriers. By contrast, a material layer, which extends around the thermal channel structure, comprises any of various suitable semiconductor materials (and/or insulator materials) which conduct heat via phonons. To facilitate an efficient conduction of heat, some embodiments variously provide a thermal interface structure between the thermal channel structure and the material layer. In one such embodiment, the thermal interface structure has a coefficient of thermal conductivity which is between that of the thermal channel structure and that of the material layer

The technologies described herein may be implemented in one or more electronic devices. Non-limiting examples of electronic devices that may utilize the technologies described herein include any kind of mobile device and/or stationary device, such as cameras, cell phones, computer terminals, desktop computers, electronic readers, facsimile machines, kiosks, laptop computers, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. More generally, the technologies described herein may be employed in any of a variety of electronic devices including an IC die which comprises a thermal channel structure.

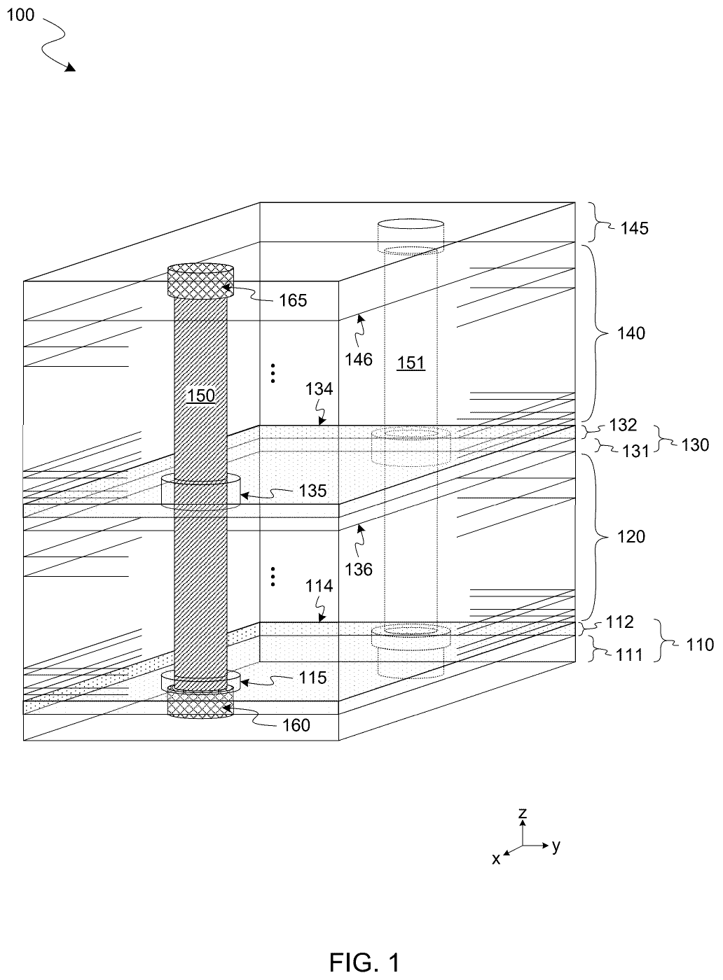

FIG. 1 shows features of an IC die structure 100 comprising thermal conduction structures according to an embodiment. IC die structure 100 illustrates one example of an embodiment wherein a thermal channel structure extends through one or more active layers of an IC die, wherein the thermal channel structure facilitates a conduction of heat across some or all of said one or more active layers.

As shown in FIG. 1, IC die structure 100 comprises lateral surfaces each along a respective x-y plane that may be defined or taken at any vertical position of IC die structure 100. The lateral surface of the x-y plane is orthogonal to a vertical or build-up dimension as defined by the z-axis. In some embodiments, IC die structure 100 may be formed from, or on, any of various substrate materials—e.g., comprising the illustrative semiconductor layer 111 shown—which are suitable for the fabrication of transistors, diodes and/or other such active (or other) circuit components. In some embodiments, a semiconductor layer 111 is used to manufacture circuit components 112 which, for example, include any of various suitable transistors, diodes, or the like of IC die structure 100. The semiconductor layer 111 may include that of a wafer or other piece of silicon or another semiconductor material. Suitable semiconductor substrates include, but are not limited to, single crystal silicon, polycrystalline silicon and silicon on insulator (SOI), as well as similar substrates formed of other semiconductor materials, such as gallium arsenide. The substrate may also include semiconductor materials, metals, dielectrics, dopants, and other materials commonly found in semiconductor substrates.

In FIG. 1, IC die structure 100 includes an IC die structure 100—such as a monolithic IC structure or a composite IC structure—which comprises multiple active layers which are in a stacked configuration with each other. In an embodiment, IC die structure 100 further comprises metallization layers which are variously disposed each between a respective two of the active layers, on a topmost one of the active layers, or (for example) under a bottommost one of the active layers.

In the example embodiment shown, an active layer 110 of IC die structure 100 comprises semiconductor layer 111 and circuit components 112, structures of which are variously formed in or on semiconductor layer 111. By way of illustration and not limitation, circuit components 112 comprise any of various suitable metal oxide semiconductor field effect transistors (MOSFETs) including one or more types of planar transistors and/or one or more types of non-planar transistors (such as tri-gate transistors, gate-all-around transistors, or the like).

In an embodiment, IC die structure 100 further comprises metallization layers 120 which are disposed on a back side of active layer 110. As used herein, the term “metallization layer” describes layers with interconnections or wires that provide electrical routing, generally formed of metal or other electrically and thermally conductive material. For example, interconnect structures of metallization layers 120 are to variously facilitate electrical coupling between circuits of active layer 110 and/or between other circuits which are to operate with active layer 110.

In one such embodiment, another active layer 130 of IC die structure 100 comprises a semiconductor layer 131 and circuit components 132, structures of which are variously formed in or on semiconductor layer 131. By way of illustration and not limitation, circuit components 112 comprise any of various suitable MOSFETs including planar transistors, non-planar transistors, and/or the like. In various embodiments, one active layer of IC die structure 100 comprises transistors of a memory array—e.g., wherein another active layer of IC die structure 100 of comprises transistors of another memory array, and/or comprises peripheral circuit logic (such as sense amplifiers, driver circuits, or the like) which facilitates access to one or more memory arrays. However, some embodiments are not limited regarding a particular functionality which is provided with a given one or more active layers of IC die structure 100.

In an embodiment, active layers 110, 130 are vertically stacked with each other—e.g., wherein metallization layers 120 and a portion of semiconductor layer 131 are disposed between circuit components 132 and active layer 110. In some embodiments, IC die structure 100 further comprises further comprises metallization layers 140 which are disposed on a back side of active layer 130. For example, interconnect structures of metallization layers 140 are to variously facilitate electrical coupling between circuits of active layer 130, between respective circuits of active layers 110, 130, and/or with other circuitry of IC die structure 100.

To facilitate heat dissipation, IC die structure 100 further comprises a thermal channel structure 150 which extends through one or more active layers, wherein thermal channel structure 150 is thermally coupled to conduct heat between material layers on opposite respective sides of at least one such active layer. In some embodiments, thermal channel structure 150 comprises any of various suitable thermally conductive metal (or other) materials. For example, thermal channel structure 150 comprises a metal such as copper, or any of various thermally conductive electrical insulators, such as aluminum nitride.

In the example embodiment shown, thermal channel structure 150 comprises a substantially columnar portion which extends through active layer 130—e.g., as well as through metallization layers 120 and through metallization layers 140—to each of semiconductor layer 111 and a heat conductive layer 145 which is disposed directly (or alternatively, indirectly) over metallization layers 140. More particularly, thermal channel structure 150 extends through a side 114 of active layer 110 and at least partially into semiconductor layer 111—e.g., wherein semiconductor layer 111 extends around a first distal end of thermal channel structure 150. In an embodiment, thermal channel structure 150 extends through a region 115 of active layer 110 which, for example, provides at least partial electrical insulation of thermal channel structure 150 from some or all of circuit components 112.

In one such embodiment, a thermal interface structure 160 extends around (and, for example, under) the first distal end of thermal channel structure 150, wherein thermal interface structure 160 is between semiconductor layer 111 and a portion of thermal channel structure 150 which is surrounded by semiconductor layer 111. In an embodiment, thermal interface structure 160 acts as a liner structure to facilitate thermal conduction between thermal channel structure 150 and semiconductor layer 111. For example, a material of the thermal interface structure 160 has a coefficient of thermal conductivity which is between the respective coefficients of thermal conductivity of thermal channel structure 150 and semiconductor layer 111. By way of illustration and not limitation, thermal interface structure 160 comprises aluminum nitride—e.g., wherein thermal channel structure 150 comprises copper and semiconductor layer 111 is a semiconductor comprising silicon. In another embodiment, thermal interface structure 160 comprises silicon carbide—e.g., wherein thermal channel structure 150 comprises aluminum nitride and semiconductor layer 111 is a semiconductor comprising silicon.

In some embodiments, thermal channel structure 150 further extends through a side 146 of metallization layers 140 and at least partially into heat conductive layer 145—e.g., wherein heat conductive layer 145 extends around a second distal end of thermal channel structure 150. In an embodiment, heat conductive layer 145 comprises any of various suitable materials—e.g., comprising a semiconductor material or a dielectric material-which facilitates conduction of heat to or from thermal channel structure 150. By way of illustration and not limitation, a thermally conductive material of heat conductive layer 145 is similar to that in semiconductor layer 111 or semiconductor layer 131, or to that in a carrier wafer, a passivation layer, or the like.

In various embodiments, a thermal interface structure 165 (e.g., including aluminum nitride) extends around—and, for example, over—the second distal end of thermal channel structure 150, wherein thermal interface structure 165 is between heat conductive layer 145 and a portion of thermal channel structure 150 which is surrounded by heat conductive layer 145. In an embodiment, thermal interface structure 165 acts as a liner structure to facilitate thermal conduction between thermal channel structure 150 and heat conductive layer 145. For example, a material of the thermal interface structure 165 has a coefficient of thermal conductivity which is between the respective coefficients of thermal conductivity of thermal channel structure 150 and heat conductive layer 145.

In various embodiments, thermal channel structure 150 extends vertically (in a z-axis direction) through a portion of a given active layer, and is surrounded in a horizontal (x-y) plane by said portion of the given active layer. In one such embodiment, thermal channel structure 150 is electrically insulated, at least partially, by a surrounding portion of the given active layer. Alternatively or in addition, thermal channel structure 150 is thermally insulated, at least partially, by the surrounding portion of the given active layer. Alternatively, thermal channel structure 150 is thermally coupled to a surrounding portion of the active layer—e.g., by another thermal interface structure which is between thermal channel structure 150 and that surrounding portion of the active layer.

In the example embodiment shown, thermal channel structure 150 extends through a region 135 between opposite sides side 134, 136 of active layer 130. In some embodiments, a material in region 135 facilitates electrical insulation of thermal channel structure 150 at least between sides 134, 136. In one such embodiment, region 135 includes a thermal insulator material to mitigate a conduction of heat between thermal channel structure 150 and active layer 130 between sides 134, 136. Alternatively, region 135 includes a thermal interface structure—e.g., including a material similar to that of thermal interface structure 160—which has a coefficient of thermal conductivity between the respective coefficients of thermal conductivity of thermal channel structure 150 and semiconductor layer 131.

In some embodiments, thermal channel structure 150—in addition to facilitating a conduction of heat between two or more material layers (and through at least one active layer)—is electrically coupled to one or more circuit structures of IC die structure 100. For example, in various embodiments, thermal channel structure 150 comprises a metal (e.g., copper) and is electrically coupled to one or more interconnect structures each in a respective one of metallization layers 120 and metallization layers 140. In one such embodiment, thermal channel structure 150 is electrically coupled to each of a first interconnect structure of metallization layers 120, and a second interconnect structure of metallization layers 140. For example, thermal channel structure 150 is electrically coupled to facilitate power delivery to circuit components 112 and/or to circuit components 132 via metallization layers 120 and metallization layers 140.

Although thermal channel structure 150 is shown as extending entirely through only one active layer—i.e., active layer 130—in other embodiments, thermal channel structure 150 further extends through one or more other active layers (not shown) of IC die structure 100. For example, in one such embodiment, another active layer of IC die structure 100 is between active layer 130 and heat conductive layer 145, or is between active layer 130 and active layer 110.

In some embodiments, IC die structure 100 further comprises one or more additional thermal channel structures which variously have features similar to those of thermal channel structure 150. By way of illustration and not limitation, another (optional) thermal channel structure 151 also extends through metallization layers 120, active layer 130 and metallization layers 140 to each of semiconductor layer 111 and heat conductive layer 145. In one such embodiment, an additional thermal interface structure is disposed between semiconductor layer 111 and one distal end of thermal channel structure 151—e.g., wherein still another thermal interface structure is disposed between heat conductive layer 145 and another distal end of thermal channel structure 151.

In the example embodiment shown, a main body portion of thermal channel structure 150 is substantially columnar along the entire vertical (z-axis) distance between semiconductor layer 111 and heat conductive layer 145. For example, a horizontal (x-y plane) dimension of such a main body portion at side 114 is, in one such embodiment, within 10% of a corresponding horizontal dimension of the main body portion at heat conductive layer 145.

In an alternative embodiment, a main body portion of thermal channel structure 150 tapers along the entire vertical (z-axis) distance between semiconductor layer 111 and heat conductive layer 145. By way of illustration and not limitation, a horizontal (x-y plane) dimension of such a main body portion at side 114 differs by at least 10% of a corresponding horizontal dimension of the main body portion at heat conductive layer 145

Alternatively or in addition, in various embodiments, a cross-sectional dimension—e.g., an x-axis length or a y-axis width—of thermal channel structure 150 at a given height in metallization layers 120 (or in metallization layers 140, for example) is multiple times greater than a corresponding cross-sectional dimension of a via structure which also extends in the same given height. In one such embodiment, such a cross-sectional dimension of thermal channel structure 150 is at least five times (and in some embodiments, at least ten times) the cross-sectional dimension of a via structure at the given height.

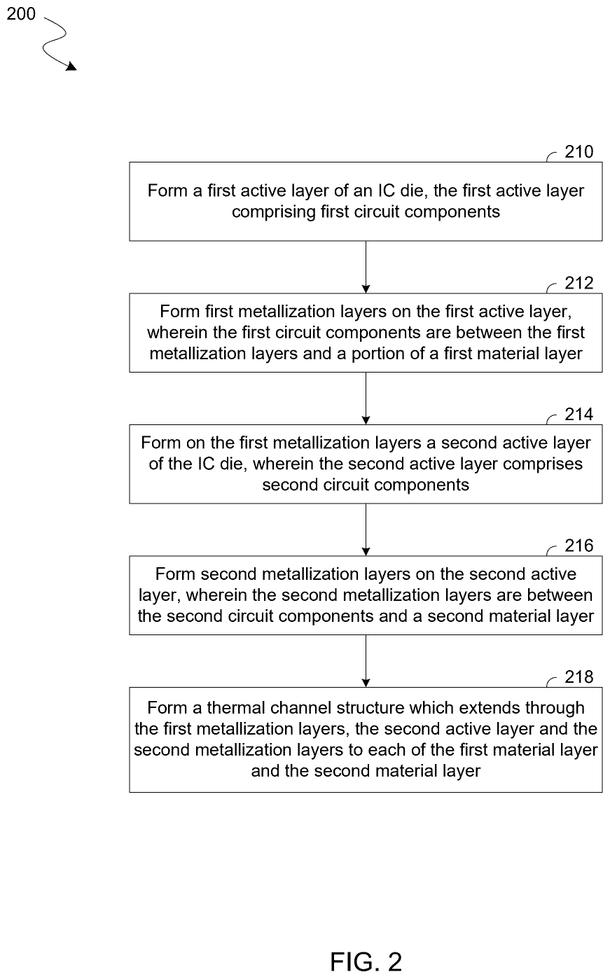

FIG. 2 shows a method 200 for providing thermal channel structures of an IC die according to an embodiment. Method 200 illustrates one example of an embodiment which enables an IC die to efficiently conduct heat through one or more active layers. Operations such as those of method 200 are performed to provide some or all of the functionality of IC die structure 100, for example.

As shown in FIG. 2, method 200 comprises (at 210) forming a first active layer of an IC die, the first active layer comprising first circuit components. For example, the forming at 210 comprises performing patterned mask, lithography, deposition and/or other suitable processes—e.g., adapted from conventional semiconductor fabrication techniques—to manufacture transistors, diodes and/or other active circuit components such as those of active layer 110. In an embodiment, the first circuit components are formed on a substrate comprising a first semiconductor material. By way of illustration and not limitation, the first semiconductor material comprises a monocrystalline semiconductor material such as, but not limited to, predominantly silicon (e.g., substantially pure Si) material, predominantly germanium (e.g., substantially pure Ge) material, or a compound material comprising a Group IV majority constituent (e.g., SiGe alloys, GeSn alloys). In various embodiments, the first semiconductor material is a Group III-N material comprising a Group III majority constituent and nitrogen as a majority constituent (e.g., GaN, InGaN). In another embodiment, the first semiconductor material is a Group III-V material comprising a Group III majority constituent and a Group IV majority constituent (e.g., InGaAs, GaAs, GaSb, InGaSb).

Method 200 further comprises (at 212) forming first metallization layers on the first active layer, wherein the first circuit components are between the first metallization layers and a portion of a first material layer. For example, the first material layer is a semiconductor substrate of the first active layer or—alternatively—is another thermally conductive material layer disposed under the first active layer. In an embodiment, the forming at 212 comprises forming one or more initial levels of patterned interconnect metallization structures which are variously embedded in, or otherwise insulated at least partially with, dielectric material structures. In an embodiment, the forming at 212 is adapted from conventional metallization techniques—e.g., wherein the patterned interconnect metallization structures at least partially provides coupling of the first active circuit components with each other and/or with other circuitry.

Method 200 further comprises (at 214) forming, on the first metallization layers, a second active layer of the IC die, wherein the second active layer comprises second circuit components. In one such embodiment, the forming at 214 comprises depositing or otherwise providing a layer of a second semiconductor material on the first metallization layers—e.g., wherein said depositing is adapted from any of various suitable semiconductor layer transfer techniques. After such depositing, one or more patterned mask, etch, deposition, and/or other suitable semiconductor fabrication operations are performed to form the second circuit components in or on the second semiconductor material.

In another such embodiment, the forming at 214 comprises fabricating the second circuit components in or on the second semiconductor material prior to a coupling of the second active layer to the first active layer (e.g., via the first metallization layers). For example, a hybrid bond (or other) assembly process is performed to couple a combination of both the second circuit components and the second semiconductor material to the first active layer (e.g., via the first metallization layer). As a result, hybrid bond structures are disposed between the first metallization layers and a substrate of the second semiconductor material.

Method 200 further comprises (at 216) forming second metallization layers on the second active layer, wherein the second metallization layers are between the second circuit components and a second material layer. For example, the second metallization layers—e.g., in combination with the first metallization layers—at least partially provide interconnection between some or all of the first active circuit components, the second circuit components, and other circuit structures of the IC die. In an embodiment, the forming at 216 comprises one or more operations are adapted from conventional metallization techniques.

Method 200 further comprises (at 218) forming a thermal channel structure which extends through the first metallization layers, the second active layer and the second metallization layers to each of the first material layer and the second material layer. In some embodiments, the forming at 218 comprises performing a patterned etch which forms a recess structure that extend through each of the first metallization layers, the second active layer and the second metallization layers. In one such embodiment, a deposition is subsequently performed to deposit a thermally conductive material into the recess structure. In other embodiments, various portions of the thermal channel structure are successively built up during the formation of some or all of the first metallization layers, the second active layer, and the second metallization layers. In various embodiments, a first thermal interface structure is disposed between the first material layer and a first distal end of the thermal channel structure. Alternatively or in addition, a second thermal interface structure is disposed between the second material layer and a second distal end of the thermal channel structure.

In some embodiments, method 200 further comprises other operations (not shown) to form one or more additional thermal channel structures of the IC die—e.g., wherein such other operations have features of the operations shown in FIG. 2. Alternatively or in addition, method 200 further comprises other operations (not shown) to form one or more other active layers and/or one or more metallization layers through which the thermal channel structure is to extend.

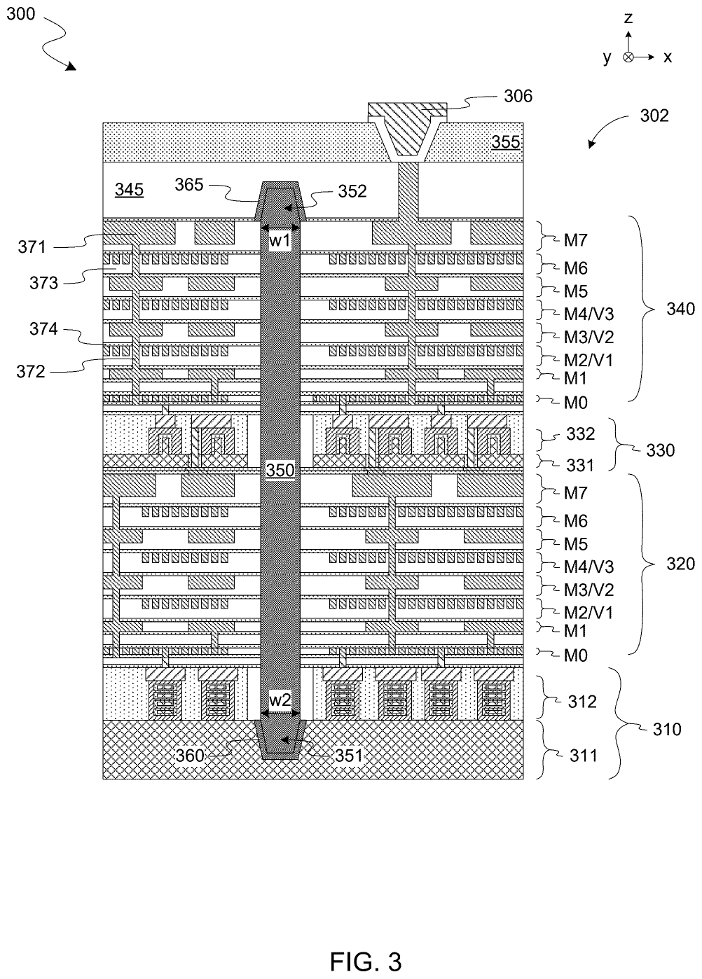

FIG. 3 shows features of an IC system 300 comprising thermal conduction structures according to an embodiment. In various embodiments, IC system 300 provides functionality such as that of IC die structure 100—e.g., wherein structures of IC system 300 are provided by one or more operations of method 200.

As shown in FIG. 3, IC system 300 includes an IC die 302, which is a monolithic (or alternatively, a composite) IC structure comprising multiple heterogeneous active layers which are stacked in various respective back-to-front arrangements with each other. In an embodiment, the IC structure of IC die 302 further comprises metallization layers which are variously disposed each between a respective two of the active layers, or (for example) on a topmost one of the active layers.

IC die 302 comprises active layers 310, 330, metallization layers 320, metallization layers 340, and a heat conductive layer 345, which correspond functionally to active layers 110, 130, metallization layers 120, metallization layers 140, and heat conductive layer 145 (respectively). Furthermore, IC die 302 comprises a thermal channel structure 350, and thermal interface structures 360, 365 which correspond functionally to thermal channel structure 150, and thermal interface structure 160, 165 (respectively)

In the example embodiment shown, active layer 310 comprises a semiconductor layer 311 and circuit components 312 which are variously formed in or on semiconductor layer 311. Metallization layers 320 are disposed on a back side of active layer 310. Adjacent metallization layers, such as metallization interconnects 371, are interconnected by vias, such as vias 372, that may be characterized as part of the metallization layers or between the metallization layers. As shown, in some embodiments, metallization layers 320 are formed over and immediately adjacent circuit components 312. In the illustrated example, metallization layers 320 include M0, V0, M1, M2/V1, M3/V2, M4/V3, and M5-M7. However, metallization layers 320 may include any number of metallization layers such as eight or more metallization layers.

In one such embodiment, active layer 330 comprises a semiconductor layer 331 and circuit components 332 which are variously formed in or on semiconductor layer 331. Active layers 310, 330 are vertically stacked with each other—e.g., wherein metallization layers 320 and a portion of semiconductor layer 331 are disposed between circuit components 332 and active layer 310. In one such embodiment, metallization layers 340 include M0, M1, M2/V1, M3/V2, M4/V3, and M5-M8. However, metallization layers 340 may include any number of metallization layers such as eight or more metallization layers.

Metallization layers 320, and metallization layers 340 are variously embedded within dielectric materials 373, 374. In the example of FIG. 3, package-level interconnects 306 are provided on or over a back of IC die 302—e.g., as bumps over a passivation layer 355. In some embodiments, IC die 302 is attached to a circuit board, a substrate, or any of various other suitable devices (not shown) by package-level interconnects 306. However, package-level interconnects 306 may be provided using any suitable interconnect structures such as bond pads, solder bumps, etc. Interconnectivity of some or all of circuit components 312, 332 (and other transistors, etc.), signal routing in a separation layer between channel stack structures, and routing to an outside device (not shown), is variously provided with some or all of metallization layers 320, metallization layers 340, and package-level interconnects 306.

To facilitate heat dissipation, IC die 302 further comprises a thermal channel structure 350 which extends through active layer 330—e.g., as well as through metallization layers 320 and through metallization layers 340—to each of semiconductor layer 311 and heat conductive layer 345. More particularly, thermal channel structure 350 extends only partially into semiconductor layer 311, wherein semiconductor layer 311 extends around a distal end 351 of thermal channel structure 350. In an embodiment, thermal interface structure 360 extends around and under the distal end 351, wherein thermal interface structure 360 is between semiconductor layer 311 and thermal channel structure 350.

Furthermore, thermal channel structure 350 extends only partially into heat conductive layer 345, wherein heat conductive layer 345 extends around a distal end 352 of thermal channel structure 350. In an embodiment, thermal interface structure 365 extends around and under the distal end 352, wherein thermal interface structure 365 is between heat conductive layer 345 and thermal channel structure 350.

In the example embodiment shown, one or more materials of active layer 330 extend between thermal channel structure 350 and semiconductor layer 331—e.g., wherein the one or more materials extend around that portion of thermal channel structure 350 which is surrounded by semiconductor layer 331. In an embodiment, the one or more materials at least partially insulate thermal channel structure 350 electrically from some or all of circuit components 332. In one such embodiment, the one or more materials also at least partially mitigate thermal transfer between channel structure 350 and semiconductor layer 331. In another such embodiment, the one or more materials promote thermally coupling between thermal channel structure 350 and semiconductor layer 331—e.g., wherein the one or more materials provide a thermal interface structure which has functionality similar to that of thermal interface structure 360 or thermal interface structure 365.

In an embodiment, a main body portion of thermal channel structure 350 is substantially columnar distance between semiconductor layer 311 and heat conductive layer 345. For example, a horizontal (x-axis) length w1 of such a main body portion at heat conductive layer 345 is within 10%—and in some embodiments, within 5%—of a length w2 of the main body portion at a top side of semiconductor layer 331.

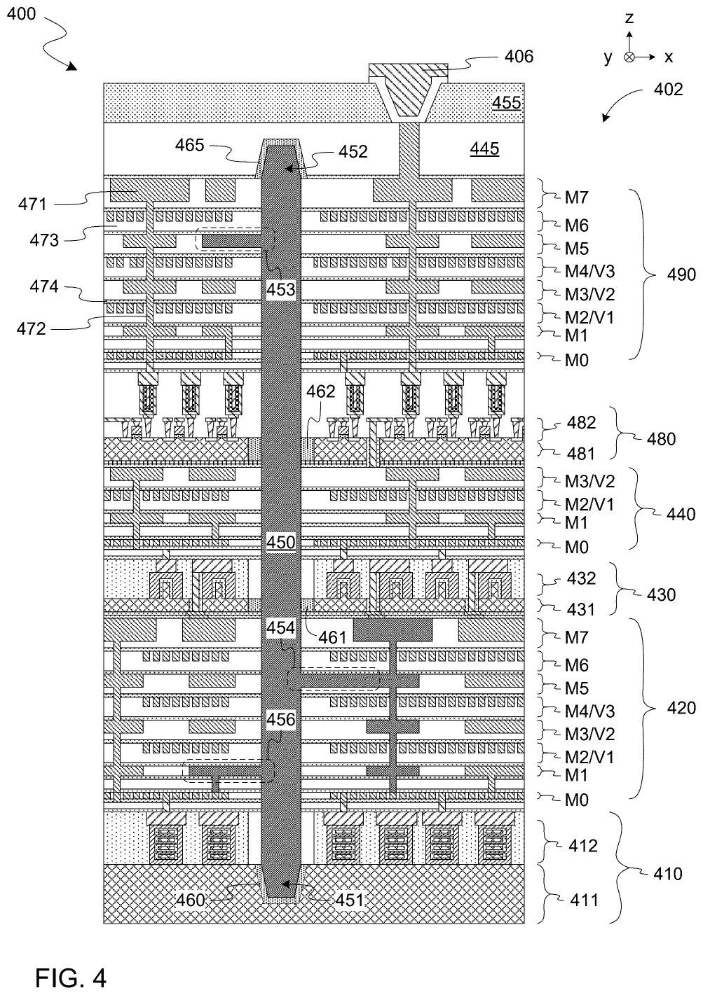

FIG. 4 shows features of an IC system 400 comprising thermal conduction structures according to another embodiment. IC system 400 illustrates one example embodiment wherein a thermal channel structure of an IC die structure comprises a metal which is electrically coupled to circuit components of the IC die structure. In various embodiments, IC system 400 provides functionality such as that of IC die structure 100—e.g., wherein structures of IC system 400 are provided by one or more operations of method 200.

As shown in FIG. 4, IC system 400 includes an IC die 402 which comprises multiple active layers and metallization layers which are variously disposed each between a respective two of the active layers, on a topmost one of the active layers, or under a bottommost one of the active layers. In the example embodiment shown, IC die 402 comprises active layers 410, 430, 480, metallization layers 420, metallization layers 440, metallization layers 490, and a heat conductive layer 445, which variously provide functionality such as that of active layers 310, 330, metallization layers 320, metallization layers 340, and heat conductive layer 345.

Active layer 410 comprises a semiconductor layer 411 and circuit components 412 which are variously formed in or on semiconductor layer 411. Furthermore, active layer 430 comprises a semiconductor layer 431 and circuit components 432 which are variously formed in or on semiconductor layer 431. Further still, active layer 480 comprises a semiconductor layer 481 and circuit components 482 which are variously formed in or on semiconductor layer 481. Metallization layers 420, metallization layers 440 and metallization layers 490 variously comprise respective metallization interconnects 471, vias 472, and/or other suitable interconnect structures, which are variously embedded within dielectric materials 473, 474. Additional electrical connectivity is facilitated, for example, with package-level interconnects 406 which are coupled to metallization layers 490 via a passivation layer 455.

Furthermore, IC die 402 comprises a thermal channel structure 450, and thermal interface structures 460, 465 which correspond functionally to thermal channel structure 350, and thermal interface structure 360, 365 (respectively). Thermal channel structure 450 extends through active layers 430, 480—as well as through metallization layers 420, metallization layers 440 and metallization layers 490—to each of heat conductive layer 445 and semiconductor layer 411. In a horizontal (x-y) plane, a distal end 451 of thermal channel structure 450 is surrounded by semiconductor layer 411, wherein thermal interface structure 460 is between semiconductor layer 411 and thermal channel structure 450. Furthermore, another distal end 452 of thermal channel structure 450 is surrounded by heat conductive layer 445, wherein thermal interface structure 465 is between heat conductive layer 445 and thermal channel structure 450.

In the example embodiment shown, semiconductor layer 431 extends around a portion of thermal channel structure 450, wherein an additional thermal interface structure 461 of IC die 402 is between semiconductor layer 431 and said portion of thermal channel structure 450. In an embodiment, a coefficient of thermal conductivity of thermal interface structure 461 is between the respective coefficients of thermal conductivity of thermal channel structure 450 and semiconductor layer 431—e.g., wherein thermal interface structures 460, 461 comprise the same material (such as aluminum nitride).

Alternatively or in addition, semiconductor layer 481 extends around a different portion of thermal channel structure 450, wherein another thermal interface structure 462 of IC die 402 is between semiconductor layer 481 and said different portion. In an embodiment, a coefficient of thermal conductivity of thermal interface structure 461 is between the respective coefficients of thermal conductivity of thermal channel structure 450 and semiconductor layer 481—e.g., wherein two or more of thermal interface structures 460, 461, 462 comprise the same material.

Although some embodiments are not limited in this regard, thermal channel structure 450 comprises a conductor (such as copper and/or any of various other suitable metals) which is electrically coupled to one or more interconnect structures of metallization layers 420, metallization layers 440, and/or metallization layers 490. By way of illustration and not limitation, thermal channel structure 450 comprises a main body portion (which, for example, is substantially columnar), from which one or more interconnect structures variously extend. In the illustrative embodiment shown, metallization layers 490 comprises an interconnect structure 453 which extends from the main body portion of thermal channel structure 450—e.g., to facilitate a delivery of power to circuitry of one or more of the active layers 410, 430, 480. For example, metallization layers 420 comprises interconnect structures 454, 456 which also variously extend to said main body portion.

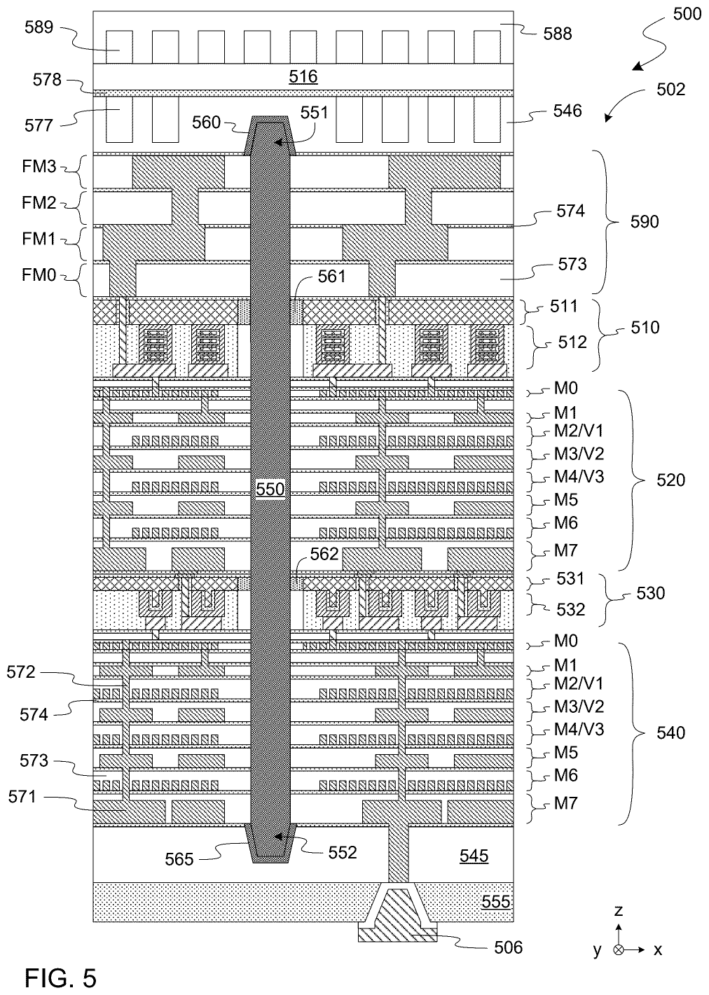

FIG. 5 shows features of an IC system 500 comprising thermal conduction structures according to an embodiment. IC system 500 illustrates one example embodiment wherein a thermal channel structure supports active cooling of an IC die structure with a heat transfer fluid. In various embodiments, IC system 500 has features of IC die structure 100, IC system 300, or IC system 400—e.g., wherein structures of IC system 500 are provided by one or more operations of method 200.

As shown in FIG. 5, IC system 500 includes an IC die 502 which comprises active layers 510, 530, (back-side) metallization layers 520, (back-side) metallization layers 540, (front-side) metallization layers 590, and a heat conductive layer 545, which variously provide functionality such as that of active layers 310, 330, metallization layers 320, metallization layers 340, and heat conductive layer 345.

Active layer 510 comprises a semiconductor layer 511 and circuit components 512 formed therein or thereon—e.g., wherein active layer 530 similarly comprises a semiconductor layer 531 and circuit components 532 formed therein or thereon. Metallization layers 520, metallization layers 540 and metallization layers 590 variously comprise respective metallization interconnects 571, vias 572, and/or other suitable interconnect structures, which are variously embedded within dielectric materials 573, 574. Additional electrical connectivity is facilitated, for example, with package-level interconnects 506 which are coupled to metallization layers 590 via a heat conductive layer 545 and a passivation layer 555.

Furthermore, IC die 502 comprises a thermal channel structure 550, and thermal interface structures 560, 565 which—for example—correspond functionally to thermal channel structure 350, and thermal interface structures 360, 365 (respectively). Thermal channel structure 550 extends through active layers 510, 530—as well as through metallization layers 520, metallization layers 540 and metallization layers 590—to each of heat conductive layer 545 and another heat conductive layer 546 on an opposite side of active layer 510. A distal end 551 of thermal channel structure 550 is surrounded by semiconductor layer 511, wherein thermal interface structure 560 is between semiconductor layer 511 and the distal end 551. Furthermore, another distal end 552 of thermal channel structure 550 is surrounded by heat conductive layer 545, wherein thermal interface structure 565 is between heat conductive layer 545 and thermal channel structure 550.

In the example embodiment shown, semiconductor layer 531 extends around a portion of thermal channel structure 550, wherein an additional thermal interface structure 561 of IC die 502 is between semiconductor layer 531 and said portion of thermal channel structure 550. Alternatively or in addition, semiconductor layer 531 extends around a different portion of thermal channel structure 550, wherein another thermal interface structure 562 of IC die 502 is between semiconductor layer 531 and said different portion.

In some embodiments, thermal channel structure 550 comprises a conductor which (for example) is further electrically coupled to one or more interconnect structures of metallization layers 520, metallization layers 540, and/or metallization layers 590. Alternatively or in addition, thermal channel structure 550 extends through more, fewer and/or other active layers of IC die 502, in some embodiments.

In the example of IC system 500, IC die 502 further includes active-cooling structures or components as provided (for example) with both die-level microchannels 577 formed in heat conductive layer 546, and with package-level active-cooling structure 588. Die-level microchannels 577 are to convey a heat transfer fluid therein to remove heat from IC die 502. The heat transfer fluid may be any suitable liquid or gas. In some embodiments, the heat transfer fluid is liquid nitrogen operable to lower the temperature of IC die 502 to a temperature at or below about −196° C. In some embodiments, the heat transfer fluid is a fluid with a cryogenic temperature operating window (e.g., about −180° C. to about −70° C.). In some embodiments, the heat transfer fluid is one of helium-3, helium-4, hydrogen, neon, air, fluorine, argon, oxygen, or methane.

As used herein, the term “microchannels” indicates a channel to convey a heat transfer fluid with the multiple microchannels providing discrete separate channels or a network of channels. Notably, the plural microchannels does not indicate separate channel networks are needed. Such die-level microchannels 577 may be provided in any pattern in the x-y plane such as serpentine patterns, patterns of multiple parallel die-level microchannels 577, or the like. Die-level microchannels 577 couple to a heat exchanger (not shown) that removes heat from and cools the heat transfer fluid before re-introduction to die-level microchannels 577. The flow of fluid within die-level microchannels 577 may be provided by a pump or other fluid flow device. The operation of the heat exchanger, pump, etc. may be controlled by a controller.

In the illustrated embodiment, die-level microchannels 577 are implemented at the heat conductive layer 546 to which thermal channel structure 550 extends. In other embodiments, die-level microchannels 577 are implemented over heat conductive layer 546. Die-level microchannels 577 may be formed using any suitable technique or techniques such as patterning and etch techniques to form the void structures of die-level microchannels 577 and passivation or deposition techniques to form a cover structure 578, a capping layer 516 and/or other structures suitable to enclose the void structures. As shown, in some embodiments, the die-level, active-cooling structure of IC system 500 includes a number of die-level microchannels 577 in IC die 502 and over a number of front-side metallization layers 590 (e.g., comprising layers FM0-FM3). As discussed, die-level microchannels 577 are to convey a heat transfer fluid therein. In some embodiments, a metallization feature of metallization layer FM3 is laterally adjacent to die-level microchannels 577. For example, metallization feature 579 may couple to a package-level interconnect structure (not shown) for signal routing for IC die 502. In some embodiments, a passive heat removal device such as a heat sink or the like may be used instead of or in addition to package-level cooling structure 588. In some embodiments, package-level cooling structure 588 is not deployed in IC system 500.

IC system 500 includes package-level active-cooling structure 588 having package-level microchannels 589. Package-level microchannels 589 are to convey a heat transfer fluid therein to remove heat from IC die 502. The heat transfer fluid may be any suitable liquid or gas as discussed with respect to die-level microchannels 577. Package-level microchannels 589 may be provided in any pattern in the x-y plane such as serpentine patterns, patterns of multiple parallel package-level microchannels 589, etc. Package-level microchannels 589 couple to a heat exchanger (not shown) that removes heat from and cools the heat transfer fluid before re-introduction to package-level microchannels 589. The flow of fluid within package-level microchannels 589 may be provided by a pump or other fluid-flow device. The operation of the heat exchanger, pump, etc. may be controlled by a controller. In the illustrated embodiment, package-level active-cooling structure 588 is a chiller mounted to IC die 502 such that the chiller has a solid body having microchannels therein to convey a heat transfer fluid.

In some embodiments, the heat-removal fluid deployed in die-level microchannels 577 and package-level active-cooling structure 588 are coupled to the same pump and heat exchanger systems. In such embodiments, the heat removal fluid conveyed in both die-level microchannels 577 and package-level active-cooling structure 588 are the same material. Such embodiments may advantageously provide simplicity. In other embodiments, the heat removal fluids are controlled separately. In such embodiments, the heat removal fluids conveyed by die-level microchannels 577 and package-level active-cooling structure 588 may be the same or they may be different. Such embodiments may advantageously provide improved flexibility.

As discussed, IC system 500 includes IC die 502 and optional die-level and package-level active-cooling structures operable to remove heat from IC die 502 to achieve a very low operating temperature of IC die 502. As used herein, the term “very low operating temperature” indicates a temperature at or below 0° C., although even lower temperatures such as an operating temperature at or below −50° C., an operating temperature at or below −70° C., an operating temperature at or below −100° C., an operating temperature at or below −180° C., or an operating temperature at or below −196° C. may be used. In some embodiments, the operating temperature is in a cryogenic temperature operating window (e.g., about −180° C. to about −70° C.). The active-cooling structure may be provided as a package-level structure (i.e., separable from IC die 502), as a die-level structure (i.e., integral to IC die 502), or both. In some embodiments, IC die 502 is deployed in a cold environment, formed using sufficiently conductive materials, etc. and an active-cooling structure is not used.

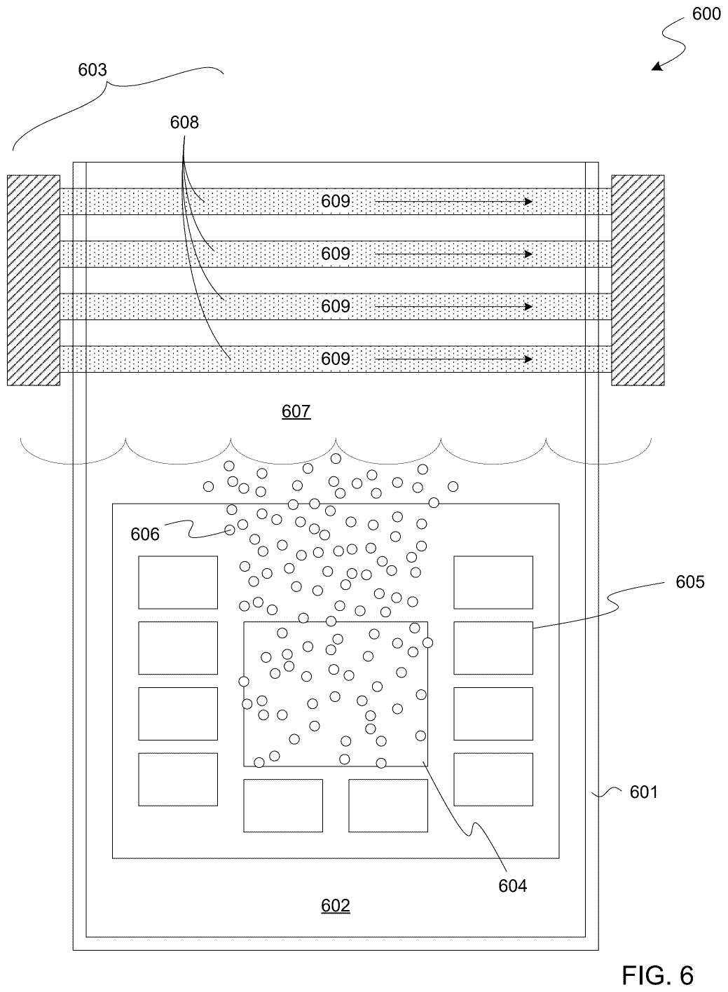

FIG. 6 illustrates a view of an example two-phase immersion cooling system 600 for low-temperature operation of an IC die, in accordance with some embodiments. As shown, two-phase immersion cooling system 600 includes a fluid containment structure 601, a low-boiling point liquid 602 within fluid containment structure 601, and a condensation structure 603 at least partially within fluid containment structure 601. As used herein, the term “low-boiling point liquid” indicates a liquid having a boiling point in the very low temperature ranges discussed. In some embodiments, the low-boiling point liquid is one of helium-3, helium-4, hydrogen, neon, air, fluorine, argon, oxygen, or methane.

In operation, a heat generation source 604, such as an IC package including any of IC die structure 100, IC system 300, IC system 400, or IC system 500 as discussed herein is immersed in low-boiling point liquid 602. In some embodiments, an IC die comprising a thermal channel structure, as deployed in two-phase immersion cooling system 600, does not include additional active cooling structures, although such die-level or package-level active cooling structures may be used in concert with two-phase immersion cooling system 600. In some embodiments, when deployed in two-phase immersion cooling system 600, package-level active-cooling structure 588 (for example) is a heat sink, a heat dissipation plate, a porous heat dissipation plate or the like.

Notably, an IC die comprising a thermal channel structure is the source of heat in the context of two-phase immersion cooling system 600. For example, an IC die comprising a thermal channel structure may be packaged and mounted on electronics substrate 605. Electronic substrate 605 may be coupled to a power supply (not shown) and may be partially or completely submerged in low-boiling point liquid 602.

In operation, the heat produced by heat generation source 604 vaporizes low-boiling point liquid 602 as shown in vapor or gas state as bubbles 606, which may collect, due to gravitational forces, above low-boiling point liquid 602 as a vapor portion 607 within fluid containment structure 601. Condensation structure 603 may extend through vapor portion 607. In some embodiments, condensation structure 603 is a heat exchanger having a number of tubes 608 with a cooling fluid (i.e., a fluid colder than the condensation point of vapor portion 607) shown by arrows 609 that may flow through tubes 608 to condense vapor portion 607 back to low-boiling point liquid 602. In the example IC system 500 of FIG. 5, package-level active-cooling structure 588 includes a passive cooling structure such as a heat sink for immersion in low-boiling point liquid 602.

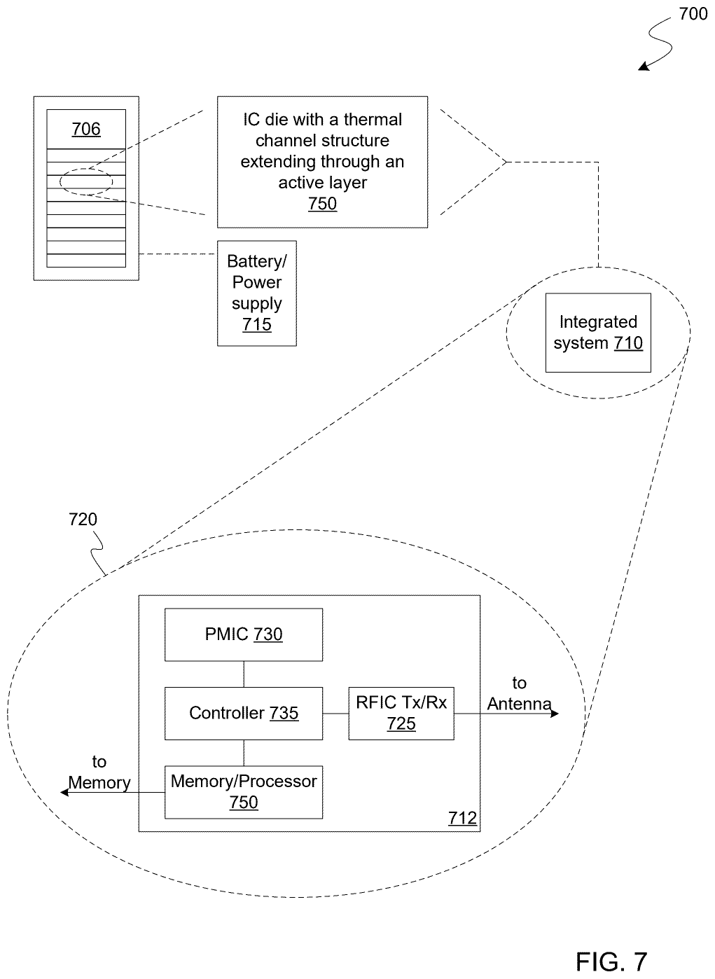

FIG. 7 illustrates a diagram of an example system 700 comprising a data server machine 706 which employs an IC die comprising one or more active layers and a thermal channel structure which extends therethrough, in accordance with some embodiments. Server machine 706 may be any commercial server, for example, including any number of high-performance computing platforms disposed within a rack and networked together for electronic data processing, which in the exemplary embodiment includes one or more devices 750 each comprising a respective IC die which includes a thermal channel structure that extends through one or more active layers.

Also as shown, server machine 706 includes a battery and/or power supply 715 to provide power to devices 750, and to provide, in some embodiments, power delivery functions such as power regulation. Devices 750 may be deployed as part of a package-level integrated system 710. Integrated system 710 is further illustrated in the expanded view 720. In the exemplary embodiment, devices 750 (labeled “Memory/Processor”) includes at least one memory chip (e.g., RAM), and/or at least one processor chip (e.g., a microprocessor, a multi-core microprocessor, or graphics processor, or the like) having the characteristics discussed herein. In an embodiment, device 750 is an IC die (e.g., including a microprocessor), a thermal channel structure of which extends through one or more active layers. As shown, device 750 may be a multi-chip module employing one or more IC dies which each comprise a respective thermal channel structure, as described herein. Device 750 may be further coupled to (e.g., communicatively coupled to) a substrate 712—e.g., such as that of a board, an interposer, or a package substrate-along with, one or more of a power management IC (PMIC) 730, RF (wireless) IC (RFIC) 725, including a wideband RF (wireless) transmitter and/or receiver (TX/RX) (e.g., including a digital baseband and an analog front end module further comprises a power amplifier on a transmit path and a low noise amplifier on a receive path), and a controller 735 thereof. In some embodiments, RFIC 725, PMIC 730, controller 735, and device 750 include one or more IC dies—e.g., in a multi-chip module—each comprising one or more active layers through which a respective thermal channel structure extends.

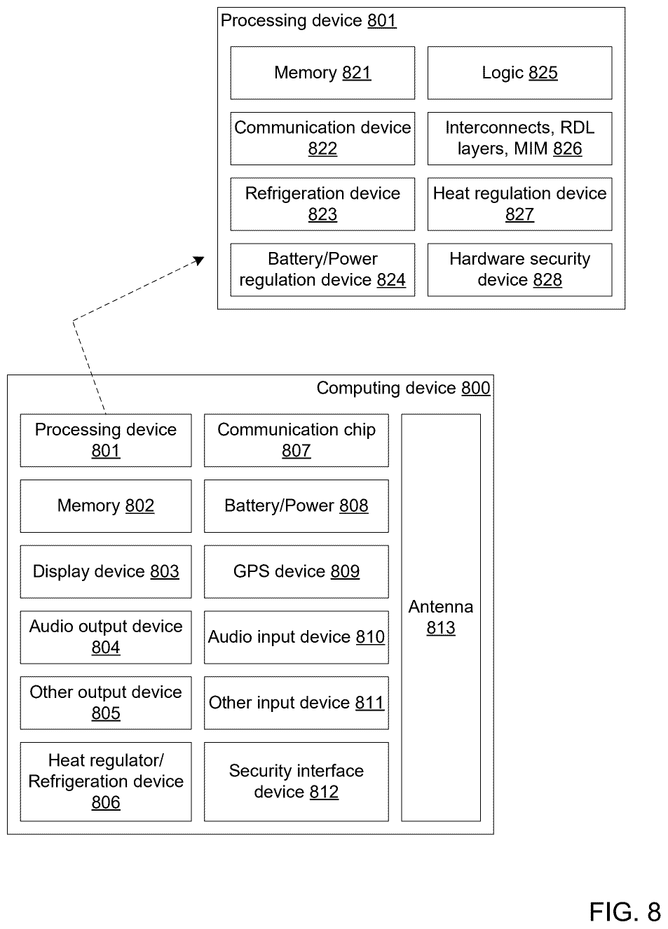

FIG. 8 is a block diagram of an example computing device 800, in accordance with some embodiments. For example, one or more components of computing device 800 may include any of the devices or structures discussed herein. A number of components are illustrated in FIG. 8 as being included in computing device 800, but any one or more of these components may be omitted or duplicated, as suitable for the application. In some embodiments, some or all of the components included in computing device 800 may be attached to one or more printed circuit boards (e.g., a motherboard). In some embodiments, various ones of these components may be fabricated onto a single system-on-a-chip (SoC) die. Additionally, in various embodiments, computing device 800 may not include one or more of the components illustrated in FIG. 8, but computing device 800 may include interface circuitry for coupling to the one or more components. For example, computing device 800 may not include a display device 803, but may include display device interface circuitry (e.g., a connector and driver circuitry) to which display device 803 may be coupled. In another set of examples, computing device 800 may not include an audio output device 804, other output device 805, global positioning system (GPS) device 809, audio input device 810, or other input device 811, but may include audio output device interface circuitry, other output device interface circuitry, GPS device interface circuitry, audio input device interface circuitry, audio input device interface circuitry, to which audio output device 804, other output device 805, GPS device 809, audio input device 810, or other input device 811 may be coupled.

Computing device 800 may include a processing device 801 (e.g., one or more processing devices). As used herein, the term “processing device” or “processor” indicates a device that processes electronic data from registers and/or memory (such as SRAM) to transform that electronic data into other electronic data that may be stored in registers and/or memory (e.g., SRAM). Processing device 801 may include a memory 821 (itself including SRAM), a communication device 822, a refrigeration device 823, a battery/power regulation device 824, logic 825, interconnects 826 (i.e., optionally including redistribution layers (RDL) or metal-insulator-metal (MIM) devices), a heat regulation device 827, and a hardware security device 828.

Processing device 801 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 800 may include a memory 802, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 802 includes memory that shares a die with processing device 801. This memory may be used as cache memory and may include embedded dynamic random-access memory (eDRAM) or spin transfer torque magnetic random-access memory (STT-M RAM).

Computing device 800 may include a heat regulation/refrigeration device 806. Heat regulation/refrigeration device 806 may maintain processing device 801 (and/or other components of computing device 800) at a predetermined low temperature during operation. This predetermined low temperature may be any temperature discussed herein.

In some embodiments, computing device 800 may include a communication chip 807 (e.g., one or more communication chips). For example, the communication chip 807 may be configured for managing wireless communications for the transfer of data to and from computing device 800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 807 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 807 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 807 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 807 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 807 may operate in accordance with other wireless protocols in other embodiments. Computing device 800 may include an antenna 813 to facilitate wireless communications and/or to receive other wireless communications (such as AM or FM radio transmissions).

In some embodiments, communication chip 807 may manage wired communications, such as electrical, optical, or any other suitable communication protocols (e.g., the Ethernet). As noted above, communication chip 807 may include multiple communication chips. For instance, a first communication chip 807 may be dedicated to shorter-range wireless communications such as Wi-Fi or Bluetooth, and a second communication chip 807 may be dedicated to longer-range wireless communications such as GPS, EDGE, GPRS, CDMA, WiMAX, LTE, EV-DO, or others. In some embodiments, a first communication chip 807 may be dedicated to wireless communications, and a second communication chip 807 may be dedicated to wired communications.

Computing device 800 may include battery/power circuitry 808. Battery/power circuitry 808 may include one or more energy storage devices (e.g., batteries or capacitors) and/or circuitry for coupling components of computing device 800 to an energy source separate from computing device 800 (e.g., AC line power).

Computing device 800 may include a display device 803 (or corresponding interface circuitry, as discussed above). Display device 803 may include any visual indicators, such as a heads-up display, a computer monitor, a projector, a touchscreen display, a liquid crystal display (LCD), a light-emitting diode display, or a flat panel display, for example.

Computing device 800 may include an audio output device 804 (or corresponding interface circuitry, as discussed above). Audio output device 804 may include any device that generates an audible indicator, such as speakers, headsets, or earbuds, for example.

Computing device 800 may include an audio input device 810 (or corresponding interface circuitry, as discussed above). Audio input device 810 may include any device that generates a signal representative of a sound, such as microphones, microphone arrays, or digital instruments (e.g., instruments having a musical instrument digital interface (MIDI) output).

Computing device 800 may include a GPS device 809 (or corresponding interface circuitry, as discussed above). GPS device 809 may be in communication with a satellite-based system and may receive a location of computing device 800, as known in the art.

Computing device 800 may include other output device 805 (or corresponding interface circuitry, as discussed above). Examples of the other output device 805 may include an audio codec, a video codec, a printer, a wired or wireless transmitter for providing information to other devices, or an additional storage device.

Computing device 800 may include other input device 811 (or corresponding interface circuitry, as discussed above). Examples of the other input device 811 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 800 may include a security interface device 812. Security interface device 812 may include any device that provides security measures for computing device 800 such as intrusion detection, biometric validation, security encode or decode, access list management, malware detection, or spyware detection.

Computing device 800, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The description herein includes numerous details to provide a more thorough explanation of the embodiments of the present disclosure. It will be apparent to one skilled in the art, however, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate a greater number of constituent signal paths, and/or have arrows at one or more ends, to indicate a direction of information flow. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The term “device” may generally refer to an apparatus according to the context of the usage of that term. For example, a device may refer to a stack of layers or structures, a single structure or layer, a connection of various structures having active and/or passive elements, etc. Generally, a device is a three-dimensional structure with a plane along the x-y direction and a height along the z direction of an x-y-z Cartesian coordinate system. The plane of the device may also be the plane of an apparatus which comprises the device.

The term “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up—i.e. scaling down, or scaling up respectively) of a signal frequency relative to another parameter, for example, power supply level.

The terms “substantially,” “close,” “approximately,” “near,” and “about,” generally refer to being within +/−10% of a target value. For example, unless otherwise specified in the explicit context of their use, the terms “substantially equal,” “about equal” and “approximately equal” mean that there is no more than incidental variation between among things so described. In the art, such variation is typically no more than +/−10% of a predetermined target value.

It is to be understood that the terms so used are interchangeable under appropriate circumstances such that the embodiments of the invention described herein are, for example, capable of operation in other orientations than those illustrated or otherwise described herein.

Unless otherwise specified the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

The terms “left,” “right,” “front,” “back,” “top,” “bottom,” “over,” “under,” and the like in the description and in the claims, if any, are used for descriptive purposes and not necessarily for describing permanent relative positions. For example, the terms “over,” “under,” “front side,” “back side,” “top,” “bottom,” “over,” “under,” and “on” as used herein refer to a relative position of one component, structure, or material with respect to other referenced components, structures or materials within a device, where such physical relationships are noteworthy. These terms are employed herein for descriptive purposes only and predominantly within the context of a device z-axis and therefore may be relative to an orientation of a device. Hence, a first material “over” a second material in the context of a figure provided herein may also be “under” the second material if the device is oriented upside-down relative to the context of the figure provided. In the context of materials, one material disposed over or under another may be directly in contact or may have one or more intervening materials. Moreover, one material disposed between two materials may be directly in contact with the two layers or may have one or more intervening layers. In contrast, a first material “on” a second material is in direct contact with that second material. Similar distinctions are to be made in the context of component assemblies.

The term “between” may be employed in the context of the z-axis, x-axis or y-axis of a device. A material that is between two other materials may be in contact with one or both of those materials, or it may be separated from both of the other two materials by one or more intervening materials. A material “between” two other materials may therefore be in contact with either of the other two materials, or it may be coupled to the other two materials through an intervening material. A device that is between two other devices may be directly connected to one or both of those devices, or it may be separated from both of the other two devices by one or more intervening devices.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. It is pointed out that those elements of a figure having the same reference numbers (or names) as the elements of any other figure can operate or function in any manner similar to that described, but are not limited to such.

In addition, the various elements of combinatorial logic and sequential logic discussed in the present disclosure may pertain both to physical structures (such as AND gates, OR gates, or XOR gates), or to synthesized or otherwise optimized collections of devices implementing the logical structures that are Boolean equivalents of the logic under discussion.

Here, multiple non-silicon semiconductor material layers may be stacked within a single fin structure. The multiple non-silicon semiconductor material layers may include one or more “P-type” layers that are suitable (e.g., offer higher hole mobility than silicon) for P-type transistors. The multiple non-silicon semiconductor material layers may further include one or more one or more “N-type” layers that are suitable (e.g., offer higher electron mobility than silicon) for N-type transistors. The multiple non-silicon semiconductor material layers may further include one or more intervening layers separating the N-type from the P-type layers. The intervening layers may be at least partially sacrificial, for example to allow one or more of a gate, source, or drain to wrap completely around a channel region of one or more of the N-type and P-type transistors. The multiple non-silicon semiconductor material layers may be fabricated, at least in part, with self-aligned techniques such that a stacked CMOS device may include both a high-mobility N-type and P-type transistor with a footprint of a single transistor.

For purposes of the embodiments, the transistors in various circuits, modules, and logic blocks are Tunneling FETs (TFETs). Some transistors of various embodiments may comprise metal oxide semiconductor (MOS) transistors, which include drain, source, gate, and bulk terminals. The transistors may also include Tri-Gate and FinFET transistors, Gate All Around Cylindrical Transistors, Square Wire, or Rectangular Ribbon Transistors or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors-BJT PNP/NPN, BICMOS, CMOS, etc., may be used for some transistors without departing from the scope of the disclosure.

In one or more first embodiments, an integrated circuit (IC) die structure comprises a first active layer comprising first circuit components, a second active layer which is stacked with the first active layer, the second active layer comprising second circuit components, first metallization layers between the first active layer and the second active layer, wherein the first circuit components are between the first metallization layers and a portion of a first material layer, second metallization layers on the second active layer, wherein the second metallization layers are between the second circuit components and a second material layer, and a thermal channel structure which extends through the first metallization layers, the second active layer and the second metallization layers to each of the first material layer and the second material layer, wherein a first thermal interface structure is disposed between the first material layer and a first distal end of the thermal channel structure, and wherein a second thermal interface structure is disposed between the second material layer and a second distal end of the thermal channel structure.

In one or more second embodiments, further to the first embodiment, the first material layer is a semiconductor substrate of the first active layer.

In one or more third embodiments, further to the first embodiment or the second embodiment, a first material of the thermal channel structure has a first coefficient of thermal conductivity, a second material of the first material layer has a second coefficient of thermal conductivity, and a third material of the first thermal interface structure has a third coefficient of thermal conductivity which is between the first coefficient of thermal conductivity and the second coefficient of thermal conductivity.

In one or more fourth embodiments, further to the third embodiment, a fourth material of the second material layer has a fourth coefficient of thermal conductivity, and a fifth material of the second thermal interface structure has a fifth coefficient of thermal conductivity which is between the first coefficient of thermal conductivity and the fourth coefficient of thermal conductivity.

In one or more fifth embodiments, further to the first embodiment or the second embodiment, the thermal channel structure comprises a metal.

In one or more sixth embodiments, further to the fifth embodiment, the thermal channel structure is electrically coupled to an interconnect structure of the first metallization layers and the second metallization layers.

In one or more seventh embodiments, further to the sixth embodiment, the thermal channel structure is electrically coupled to each of a first interconnect structure of the first metallization layers, and a second interconnect structure of the second metallization layers.

In one or more eighth embodiments, further to the first embodiment or the second embodiment, the IC die further comprises a third active layer which is stacked with the first active layer and the second active layer, the third active layer comprising third circuit components, and third metallization layers on the third active layer, wherein the third metallization layers are between the third circuit components and the second material layer, wherein the thermal channel structure further extends through the third active layer and the third metallization layers to each of the first material layer and the second material layer.

In one or more ninth embodiments, further to the first embodiment or the second embodiment, the thermal channel structure is a first thermal channel structure, the IC die further comprises a second thermal channel structure which extends through the first metallization layers, the second active layer and the second metallization layers to each of the first material layer and the second material layer, wherein a third thermal interface structure is disposed between the first material layer and a third distal end of the second thermal channel structure, and wherein a fourth thermal interface structure is disposed between the second material layer and a fourth distal end of the second thermal channel structure.

In one or more tenth embodiments, a method comprises forming a first active layer of an integrated circuit (IC) die, the first active layer comprising first circuit components, forming a second active layer of the IC die, wherein the second active layer is stacked with the first active layer, the second active layer comprising second circuit components, forming first metallization layers between the first active layer and the second active layer, wherein the first circuit components are between the first metallization layers and a portion of a first material layer, forming second metallization layers on the second active layer, wherein the second metallization layers are between the second circuit components and a second material layer, and forming a thermal channel structure which extends through the first metallization layers, the second active layer and the second metallization layers to each of the first material layer and the second material layer, wherein a first thermal interface structure is disposed between the first material layer and a first distal end of the thermal channel structure, and wherein a second thermal interface structure is disposed between the second material layer and a second distal end of the thermal channel structure.

In one or more eleventh embodiments, further to the tenth embodiment, the first material layer is a semiconductor substrate of the first active layer.

In one or more twelfth embodiments, further to the tenth embodiment or the eleventh embodiment, a first material of the thermal channel structure has a first coefficient of thermal conductivity, a second material of the first material layer has a second coefficient of thermal conductivity, and a third material of the first thermal interface structure has a third coefficient of thermal conductivity which is between the first coefficient of thermal conductivity and the second coefficient of thermal conductivity.

In one or more thirteenth embodiments, further to the twelfth embodiment, a fourth material of the second material layer has a fourth coefficient of thermal conductivity, and a fifth material of the second thermal interface structure has a fifth coefficient of thermal conductivity which is between the first coefficient of thermal conductivity and the fourth coefficient of thermal conductivity.

In one or more fourteenth embodiments, further to the tenth embodiment or the eleventh embodiment, the thermal channel structure comprises a metal.

In one or more fifteenth embodiments, further to the fourteenth embodiment, the thermal channel structure is electrically coupled to an interconnect structure of the first metallization layers and the second metallization layers.

In one or more sixteenth embodiments, further to the fifteenth embodiment, the thermal channel structure is electrically coupled to each of a first interconnect structure of the first metallization layers, and a second interconnect structure of the second metallization layers.

In one or more seventeenth embodiments, further to the tenth embodiment or the eleventh embodiment, the method further comprises forming a third active layer of the IC die, wherein the third active layer is stacked with the first active layer and the second active layer, the third active layer comprising third circuit components, and forming third metallization layers on the third active layer, wherein the third metallization layers are between the third circuit components and the second material layer, wherein the thermal channel structure further extends through the third active layer and the third metallization layers to each of the first material layer and the second material layer.

In one or more eighteenth embodiments, further to the tenth embodiment or the eleventh embodiment, the thermal channel structure is a first thermal channel structure, the method further comprises forming a second thermal channel structure which extends through the first metallization layers, the second active layer and the second metallization layers to each of the first material layer and the second material layer, wherein a third thermal interface structure is disposed between the first material layer and a third distal end of the second thermal channel structure, and wherein a fourth thermal interface structure is disposed between the second material layer and a fourth distal end of the second thermal channel structure.

In one or more nineteenth embodiments, a system comprises a substrate, and a component coupled to the substrate, the component comprising an integrated circuit (IC) die, wherein the IC die comprises a first active layer comprising first circuit components, a second active layer which is stacked with the first active layer, the second active layer comprising second circuit components, first metallization layers between the first active layer and the second active layer, wherein the first circuit components are between the first metallization layers and a portion of a first material layer, second metallization layers on the second active layer, wherein the second metallization layers are between the second circuit components and a second material layer, and a thermal channel structure which extends through the first metallization layers, the second active layer and the second metallization layers to each of the first material layer and the second material layer, wherein a first thermal interface structure is disposed between the first material layer and a first distal end of the thermal channel structure, and wherein a second thermal interface structure is disposed between the second material layer and a second distal end of the thermal channel structure.

In one or more twentieth embodiments, further to the nineteenth embodiment, the first material layer is a semiconductor substrate of the first active layer.

In one or more twenty-first embodiments, further to the nineteenth embodiment or the twentieth embodiment, a first material of the thermal channel structure has a first coefficient of thermal conductivity, a second material of the first material layer has a second coefficient of thermal conductivity, and a third material of the first thermal interface structure has a third coefficient of thermal conductivity which is between the first coefficient of thermal conductivity and the second coefficient of thermal conductivity.

In one or more twenty-second embodiments, further to the twenty-first embodiment, a fourth material of the second material layer has a fourth coefficient of thermal conductivity, and a fifth material of the second thermal interface structure has a fifth coefficient of thermal conductivity which is between the first coefficient of thermal conductivity and the fourth coefficient of thermal conductivity.

In one or more twenty-third embodiments, further to the nineteenth embodiment or the twentieth embodiment, the thermal channel structure comprises a metal.

In one or more twenty-fourth embodiments, further to the twenty-third embodiment, the thermal channel structure is electrically coupled to an interconnect structure of the first metallization layers and the second metallization layers.

In one or more twenty-fifth embodiments, further to the twenty-fourth embodiment, the thermal channel structure is electrically coupled to each of a first interconnect structure of the first metallization layers, and a second interconnect structure of the second metallization layers.

In one or more twenty-sixth embodiments, further to the nineteenth embodiment or the twentieth embodiment, the IC die further comprises a third active layer which is stacked with the first active layer and the second active layer, the third active layer comprising third circuit components, and third metallization layers on the third active layer, wherein the third metallization layers are between the third circuit components and the second material layer, wherein the thermal channel structure further extends through the third active layer and the third metallization layers to each of the first material layer and the second material layer.

In one or more twenty-seventh embodiments, further to the nineteenth embodiment or the twentieth embodiment, the thermal channel structure is a first thermal channel structure, the IC die further comprises a second thermal channel structure which extends through the first metallization layers, the second active layer and the second metallization layers to each of the first material layer and the second material layer, wherein a third thermal interface structure is disposed between the first material layer and a third distal end of the second thermal channel structure, and wherein a fourth thermal interface structure is disposed between the second material layer and a fourth distal end of the second thermal channel structure.

Techniques and architectures for facilitating thermal regulation of integrated circuitry are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMS, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

What is claimed is:

1. An integrated circuit (IC) die structure comprising:
a first active layer comprising first circuit components;
a second active layer which is stacked with the first active layer, the second active layer comprising second circuit components;
first metallization layers between the first active layer and the second active layer, wherein the first circuit components are between the first metallization layers and a portion of a first material layer;
second metallization layers on the second active layer, wherein the second metallization layers are between the second circuit components and a second material layer; and
a thermal channel structure which extends through the first metallization layers, the second active layer and the second metallization layers to each of the first material layer and the second material layer, wherein a first thermal interface structure is disposed between the first material layer and a first distal end of the thermal channel structure, and wherein a second thermal interface structure is disposed between the second material layer and a second distal end of the thermal channel structure.

2. The IC die of claim 1, wherein the first material layer is a semiconductor substrate of the first active layer.

3. The IC die of claim 1, wherein:
a first material of the thermal channel structure has a first coefficient of thermal conductivity;
a second material of the first material layer has a second coefficient of thermal conductivity; and
a third material of the first thermal interface structure has a third coefficient of thermal conductivity which is between the first coefficient of thermal conductivity and the second coefficient of thermal conductivity.

4. The IC die of claim 3, wherein:
a fourth material of the second material layer has a fourth coefficient of thermal conductivity; and
a fifth material of the second thermal interface structure has a fifth coefficient of thermal conductivity which is between the first coefficient of thermal conductivity and the fourth coefficient of thermal conductivity.

5. The IC die of claim 1, wherein the thermal channel structure comprises a metal.

6. The IC die of claim 5, wherein the thermal channel structure is electrically coupled to an interconnect structure of the first metallization layers and the second metallization layers.

7. The IC die of claim 6, wherein the thermal channel structure is electrically coupled to each of:
a first interconnect structure of the first metallization layers; and
a second interconnect structure of the second metallization layers.

8. The IC die of claim 1, further comprising:
a third active layer which is stacked with the first active layer and the second active layer, the third active layer comprising third circuit components; and
third metallization layers on the third active layer, wherein the third metallization layers are between the third circuit components and the second material layer;
wherein the thermal channel structure further extends through the third active layer and the third metallization layers to each of the first material layer and the second material layer.

9. The IC die of claim 1, wherein the thermal channel structure is a first thermal channel structure, the IC die further comprising:
a second thermal channel structure which extends through the first metallization layers, the second active layer and the second metallization layers to each of the first material layer and the second material layer, wherein a third thermal interface structure is disposed between the first material layer and a third distal end of the second thermal channel structure, and wherein a fourth thermal interface structure is disposed between the second material layer and a fourth distal end of the second thermal channel structure.

10. A method comprising:
forming a first active layer of an integrated circuit (IC) die, the first active layer comprising first circuit components;
forming a second active layer of the IC die, wherein the second active layer is stacked with the first active layer, the second active layer comprising second circuit components;
forming first metallization layers between the first active layer and the second active layer, wherein the first circuit components are between the first metallization layers and a portion of a first material layer;
forming second metallization layers on the second active layer, wherein the second metallization layers are between the second circuit components and a second material layer; and
forming a thermal channel structure which extends through the first metallization layers, the second active layer and the second metallization layers to each of the first material layer and the second material layer, wherein a first thermal interface structure is disposed between the first material layer and a first distal end of the thermal channel structure, and wherein a second thermal interface structure is disposed between the second material layer and a second distal end of the thermal channel structure.

11. The method of claim 10, wherein the first material layer is a semiconductor substrate of the first active layer.

12. The method of claim 10, wherein:
a first material of the thermal channel structure has a first coefficient of thermal conductivity;
a second material of the first material layer has a second coefficient of thermal conductivity; and
a third material of the first thermal interface structure has a third coefficient of thermal conductivity which is between the first coefficient of thermal conductivity and the second coefficient of thermal conductivity.

13. The method of claim 12, wherein:
a fourth material of the second material layer has a fourth coefficient of thermal conductivity; and
a fifth material of the second thermal interface structure has a fifth coefficient of thermal conductivity which is between the first coefficient of thermal conductivity and the fourth coefficient of thermal conductivity.

14. The method of claim 10, wherein the thermal channel structure comprises a metal.

15. A system comprising:
a substrate; and
a component coupled to the substrate, the component comprising an integrated circuit (IC) die, wherein the IC die comprises:
a first active layer comprising first circuit components;
a second active layer which is stacked with the first active layer, the second active layer comprising second circuit components;
first metallization layers between the first active layer and the second active layer, wherein the first circuit components are between the first metallization layers and a portion of a first material layer;
second metallization layers on the second active layer, wherein the second metallization layers are between the second circuit components and a second material layer; and
a thermal channel structure which extends through the first metallization layers, the second active layer and the second metallization layers to each of the first material layer and the second material layer, wherein a first thermal interface structure is disposed between the first material layer and a first distal end of the thermal channel structure, and wherein a second thermal interface structure is disposed between the second material layer and a second distal end of the thermal channel structure.

16. The system of claim 15, wherein the first material layer is a semiconductor substrate of the first active layer.

17. The system of claim 15, wherein:
a first material of the thermal channel structure has a first coefficient of thermal conductivity;
a second material of the first material layer has a second coefficient of thermal conductivity; and
a third material of the first thermal interface structure has a third coefficient of thermal conductivity which is between the first coefficient of thermal conductivity and the second coefficient of thermal conductivity.

18. The system of claim 17, wherein:
a fourth material of the second material layer has a fourth coefficient of thermal conductivity; and
a fifth material of the second thermal interface structure has a fifth coefficient of thermal conductivity which is between the first coefficient of thermal conductivity and the fourth coefficient of thermal conductivity.

19. The system of claim 15, wherein the thermal channel structure comprises a metal.

20. The system of claim 19, wherein the thermal channel structure is electrically coupled to an interconnect structure of the first metallization layers and the second metallization layers.
